(19) United States
(12) Patent Application Publication
(10) Pub. No.: US 2026/0003454 A1
(43) Pub. Date: Jan. 1, 2026

(54) DISPLAY DEVICE AND ELECTRONIC DEVICE

(71) Applicant: Samsung Display Co., Ltd., Yongin-Si (KR)

(72) Inventors: EONJOO LEE, Yongin-si (KR); KI NYENG KANG, Yongin-si (KR); HYOENG-KI KIM, Yongin-si (KR); SUNGEUN LEE, Yongin-si (KR); HYEONBUM LEE, Yongin-si (KR)

(21) Appl. No.: 19/187,511

(22) Filed: Apr. 23, 2025

(30) Foreign Application Priority Data
Jul. 1, 2024 (KR) 10-2024-0086328

(51) Int. Cl. G06F 3/041; G06F 3/044; H10K 59/40; H10K 59/80

(52) U.S. Cl. CPC G06F 3/0412; G06F 3/0443; G06F 3/0446; H10K 59/40; H10K 59/8792; G06F 2203/04111

(57) ABSTRACT

A display device includes a display panel including emission and non-emission areas, the display panel including light emitting elements on the emission areas and an encapsulation layer covering the light emitting elements, a light blocking layer on the display panel and having light blocking openings above the emission areas, and an input sensing layer between the display panel and the light blocking layer. The input sensing layer includes a first sensor conductive layer on the encapsulation layer, a second sensor conductive layer on the first sensor conductive layer, a sensor insulating layer between the encapsulation layer and the second sensor conductive layer, and partition walls connected to the second sensor conductive layer and passing through at least a portion of the sensor insulating layer. Each of the partition walls includes a first surface facing one of the emission areas and a second surface that is opposite to the first surface.

### CROSS-REFERENCE TO RELATED APPLICATIONS

This U.S. non-provisional patent application claims priority under 35 U.S.C. § 119 of Korean Patent Application No. 10-2024-0086328, filed on Jul. 1, 2024, the entire contents of which are hereby incorporated by reference.

### BACKGROUND

The present disclosure herein relates to a display device, and more particularly, to a display device having improved optical characteristics.

Multimedia devices such as televisions, mobile phones, tablets, navigation systems, and game consoles include display devices that display images to a user through their display screens. The display device may include a display panel that generates an image and an input sensor that senses a user's touch.

The input sensor may include a conductor that senses an external input, and the conductor of the input sensor disposed on the display panel may affect emission efficiency of the display device or external light reflectance of the display device.

### SUMMARY

The present disclosure provides a display device having improved optical characteristics.

An embodiment of the inventive concept provides a display device including: a display panel including a plurality of emission areas and non-emission areas, the display panel including a plurality of light emitting elements respectively disposed on the emission areas and an encapsulation layer configured to cover the light emitting elements; a light blocking layer disposed on the display panel and having light blocking openings above the emission areas, respectively; and an input sensing layer disposed between the display panel and the light blocking layer. The input sensing layer includes: a first sensor conductive layer disposed on the encapsulation layer; a second sensor conductive layer on the first sensor conductive layer; a sensor insulating layer disposed between the encapsulation layer and the second sensor conductive layer; and partition walls connected to the second sensor conductive layer and passing through at least a portion of the sensor insulating layer. Each of the partition walls includes a first surface facing one of the emission areas and a second surface that is opposite to the first surface.

In an embodiment, the partition walls may be configured to surround the emission areas, respectively.

In an embodiment, the partition walls may be in contact with a top surface of the encapsulation layer.

In an embodiment, the sensor insulating layer may include a plurality of layers. The plurality of layers may include: a first sensor insulating layer disposed between the encapsulation layer and the first sensor conductive layer; and a second sensor insulating layer disposed between the encapsulation layer and the second sensor conductive layer and disposed on the first sensor insulating layer. The partition walls may pass through at least the second sensor insulating layer.

In an embodiment, the partition walls may further pass through at least a portion of the first sensor insulating layer.

In an embodiment, the partition walls may be in contact with the encapsulation layer.

In an embodiment, the second sensor insulating layer may include at least one of silicon nitride, silicon oxide, silicon oxynitride, or aluminum oxide.

In an embodiment, the second sensor insulating layer may include an organic insulating material.

In an embodiment, a spaced distance between a partition wall of the partition walls facing one emission area of the emission areas and a light blocking opening of the light blocking openings above the emission area on a plane may be 0.5 μm or less.

In an embodiment, a length of the first surface may be greater than the spaced distance.

In an embodiment, the second sensor conductive layer may include: a plurality of first sensing patterns arranged along a first direction; each of a plurality of first bridge patterns disposed between the first sensing patterns to connect adjacent first sensing patterns of the first sensing patterns to each other; and a plurality of second sensing patterns arranged along a second direction intersecting the first direction. The first sensor conductive layer may include each of a plurality of second bridge patterns disposed between the second sensing patterns on a plane and passing through the second sensor insulating layer so as to be connected to adjacent second sensing patterns of the second sensing patterns. A portion of the partition walls may be connected to any one of the second bridge patterns through the second sensor conductive layer.

In an embodiment, each of through-parts connected to the second sensing patterns by passing through the second sensor insulating layer from the plurality of second bridge patterns may have a thickness less than a thickness of each of the partition walls.

In an embodiment, an angle defined between the first surface and a top surface of the encapsulation layer may be an acute angle.

In an embodiment, the second sensor conductive layer and the partition walls may include a same material.

In an embodiment, the display device may further include an optical layer disposed on the input sensing layer and comprising a plurality of color filters respectively overlapping the plurality of emission areas.

In an embodiment of the inventive concept, a display device includes: a display panel including a plurality of emission areas and non-emission areas, the display panel including a plurality of light emitting elements respectively disposed on the emission areas and an encapsulation layer configured to cover the light emitting elements; a light blocking layer disposed on the display panel and having light blocking openings above the emission areas, respectively; and an input sensing layer disposed on the display panel. The input sensing layer includes: a sensor conductive layer disposed on the encapsulation layer; an insulating layer disposed between the encapsulation layer and the sensor conductive layer; and partition walls connected to the sensor conductive layer and passing through at least a portion of the insulating layer. A thickness of each of the partition walls is greater than a spaced distance between a partition wall of the partition walls facing one emission area of the emission areas and a light blocking opening of the light blocking openings above the emission area on a plane.

In an embodiment, the sensor conductive layer and the partition walls may include a same material.

In an embodiment, the partition walls may be in contact with a top surface of the encapsulation layer.

In an embodiment, the spaced distance may be 0.5 μm or less.

In an embodiment, the display device may further include an optical layer disposed on the input sensing layer and comprising a plurality of color filters respectively overlapping the plurality of emission areas.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept.

FIG. 1 is a perspective view of a display device according to an embodiment of the inventive concept.

FIG. 2 is a cross-sectional view of the display device according to an embodiment of the inventive concept.

FIG. 3 is a plan view of a display panel according to an embodiment of the inventive concept.

FIG. 4 is a plan view of an input sensing layer according to an embodiment of the inventive concept.

FIG. 5 is a cross-sectional view of the display device along the line II-II′ of FIG. 4 according to an embodiment of the inventive concept.

FIG. 6 is a cross-sectional view of the display device along the line II-II′ of FIG. 4 according to an embodiment of the inventive concept.

FIGS. 7A and 7B are enlarged plan views illustrating a portion of a display area of the display panel according to an embodiment of the inventive concept.

FIG. 8 is a cross-sectional view of the display device according to an embodiment of the inventive concept.

FIGS. 9A, 9B, 9C and 9D are cross-sectional views of the display device according to an embodiment of the inventive concept.

### DETAILED DESCRIPTION

In this specification, it will also be understood that when one component (or region, layer, portion) is referred to as being ‘on’, ‘connected to’, or ‘coupled to’ another component, it can be directly disposed/connected/coupled on/to the one component, or an intervening third component may also be present.

Like reference numerals refer to like elements throughout. Also, in the figures, the thickness, ratio, and dimensions of components are exaggerated for clarity of illustration. The term “and/or” includes any and all combinations of one or more of the associated components.

It will be understood that although the terms such as ‘first’ and ‘second’ are used herein to describe various elements, these elements should not be limited by these terms. The terms are only used to distinguish one component from other components. For example, a first element referred to as a first element in an embodiment can be referred to as a second element in an embodiment without departing from the scope of the appended claims. The terms of a singular form may include plural forms unless referred to the contrary.

Also, “under”, “below”, “above’, “upper”, and the like are used for explaining relation association of components illustrated in the drawings. The terms may be a relative concept and described based on directions expressed in the drawings.

The meaning of ‘include’ or ‘comprise’ specifies a property, a fixed number, a step, an operation, an element, a component or a combination thereof, but does not exclude other properties, fixed numbers, steps, operations, elements, components or combinations thereof.

Unless otherwise defined, all terms (including technical and scientific terms) used herein have the same meaning as commonly understood by a person of ordinary skill in the art to which the inventive concept belongs. In addition, terms such as those defined in commonly used dictionaries should be interpreted as having meanings consistent with their meanings in the context of the relevant technology, and unless explicitly defined, it should not be interpreted in an overly idealistic or overly formal sense.

Hereinafter, exemplary embodiments of the inventive concept will be described with reference to the accompanying drawings.

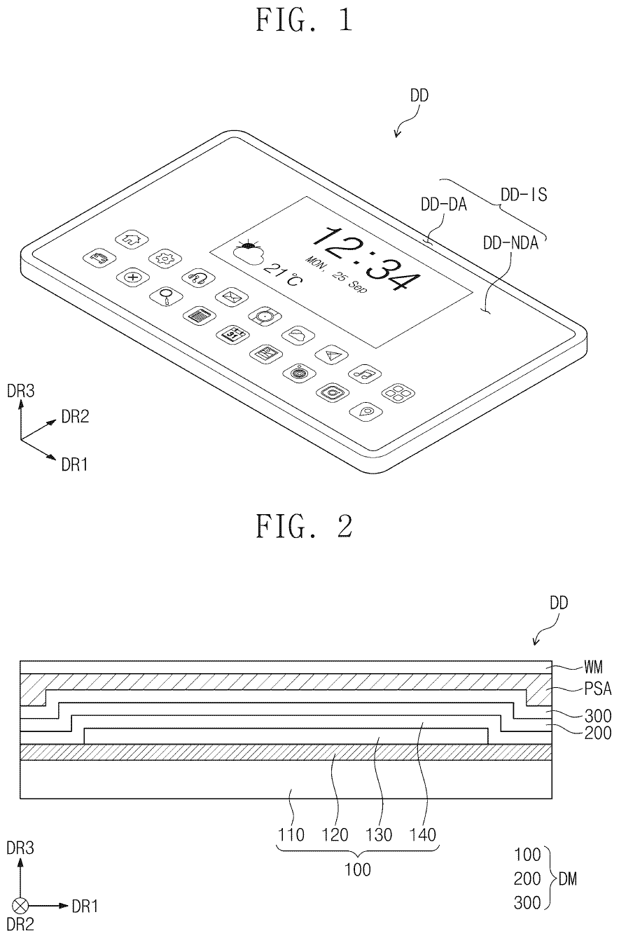

FIG. 1 is a perspective view of a display device DD according to an embodiment of the inventive concept. As illustrated in FIG. 1, the display device DD may display an image through a display surface DD-IS. The display surface DD-IS may have a rectangular shape having long sides extending in a first direction DR1 on a plane and short sides extending in a second direction DR2 intersecting the first direction DR1. However, this embodiment is not limited thereto, and the display module DM may have various shapes such as a circular shape or a polygonal shape.

In this embodiment, a third direction DR3 may be defined as a direction substantially perpendicular to a plane defined by the first direction DR1 and the second direction DR2. Front (or top) and rear (or bottom) surfaces of each member constituting the display device DD may be opposed to each other in the third direction DR3, and a normal direction of each of the front and rear surfaces may be substantially parallel to the third direction DR3. A spaced distance between the front and rear surfaces defined along the third direction DR3 may correspond to a thickness of the member.

In this specification, “on a plane” may be defined in a state when viewed in the third direction DR3. That is, “on the plane” may be described with reference to the plane defined by the first direction DR1 and the second direction DR2. In this specification, “in a cross-section” may be defined in a state when viewed in the first direction DR1 or the second direction DR2. The directions indicated as the first to third directions DR1, DR2, and DR3 may be a relative concept and thus changed into different directions.

Although the display device DD having a planar display surface is illustrated in an embodiment of the inventive concept, the embodiment of the inventive concept is not limited thereto. The display device DD may include a curved display surface or a solid display surface. The solid display surface may include a plurality of display areas that indicate different directions. For example, the solid display surface may include a bent display surface. The display device DD according to this embodiment may be a flexible display device DD. The flexible display DD may be a foldable display.

According to this embodiment, the display device DD that is capable of being applied to a tablet terminal is illustrated as an example. Electronic modules, a camera module, a power module, and the like, which are mounted on a main board, may be disposed on a bracket/case together with the display device DD to constitute the mobile terminal. The display device DD according to an embodiment of the inventive concept may be applied to large-sized electronic devices such as televisions and monitors and small and middle-sized electronic devices such as mobile phones, navigation units for vehicles, game consoles, and smart watches.

As illustrated in FIG. 1, the display surface DD-IS includes an image area DD-DA on which an image is displayed and a bezel area DD-NDA adjacent to the image area DD-DA. The bezel area DD-NDA may be an area on which an image is not displayed. FIG. 1 illustrates icon images as an example of the image.

As illustrated in FIG. 1, the image area DD-DA may have a substantially rectangular shape. The “substantially rectangular shape” includes not only a rectangular shape as a mathematical sense but also a rectangular shape in which a vertex is not defined in a vertex area (or a corner area) but a boundary of a curve is defined.

The bezel area DD-NDA may surround the image area DD-DA. However, this embodiment is not limited thereto, and the shape of the bezel area DD-NDA may be modified. For example, the bezel area DD-NDA may be disposed on only one side of the image area DD-DA.

FIG. 2 is a cross-sectional view of the display device DD according to an embodiment of the inventive concept.

The display device DD may include a display module DM and a window WM disposed on the display module DM. The display module DM and the window WM may be coupled by an adhesive layer PSA. According to an embodiment, the window WM may be provided in a coating manner, and the window WM may be in contact with the display module DM. Here, the adhesive layer PSA may be omitted.

The display module DM may include a display panel 100, an input sensing layer 200, and an optical layer 300. The display panel 100 may include a base layer 110, a driving element layer 120, a light emitting element layer 130, and an encapsulation layer 140.

A driving element layer 120 may be disposed on a top surface of the base layer 110. The base layer 110 may be a flexible substrate that is bendable, foldable, rollable, etc. The base layer 110 may be a glass substrate, a metal substrate, or a polymer substrate. However, an embodiment of the present disclosure is not limited thereto, and the base layer 110 may be an inorganic layer, an organic layer, or a composite material layer. Substantially, the base layer 110 may have the same shape as the display panel 100.

The base layer 110 may have a multilayer structure. For example, the base layer 110 may include a first synthetic resin layer, a second synthetic resin layer, and inorganic layers disposed between the first synthetic resin layer and the second synthetic resin layer. Each of the first and second synthetic resin layers may include a polyimide-based resin, but is not particularly limited thereto.

The driving element layer 120 may be disposed on the base layer 110. The driving element layer 120 may include a plurality of insulating layers, a plurality of semiconductor patterns, a plurality of conductive patterns, and signal lines. The driving element layer 120 may include a driving circuit of a pixel.

The light emitting element layer 130 may be disposed on the driving element layer 120. The light emitting element layer 130 may include a light emitting element. For example, the light emitting element may include an organic light emitting material, an inorganic light emitting material, an organic-inorganic light emitting material, a quantum dot, a quantum rod, a micro LED, or a nano LED.

The encapsulation layer 140 may be disposed on the light emitting element layer 130. The encapsulation layer 140 may protect the light emitting element layer 130, i.e., the light emitting element of the light emitting element layer 130, from foreign substances such as moisture, oxygen, and dust particles. The encapsulation layer 140 may include at least one encapsulating inorganic layer. The encapsulation layer 140 may include a laminated structure of a first encapsulating inorganic layer/encapsulating organic layer/second encapsulating inorganic layer.

The input sensing layer 200 may be disposed directly on the display panel 100. The input sensing layer 200 may sense a user's input, for example, using an electromagnetic induction manner and/or an electrostatic capacitance manner. The display panel 100 and the input sensing layer 200 may be provided through a continuous process. Here, that is “directly disposed” may mean that no third component is disposed between the input sensing layer 200 and the display panel 100. For example, a separate adhesive layer may not be disposed between the input sensing layer 200 and the display panel 100.

The optical layer 300 may reduce reflectivity of external light incident from an upper side of the window WM. The optical layer 300 according to an embodiment of the inventive concept may include a retarder and a polarizer. The retarder may be a film type or liquid crystal coating type retarder and may include a λ/2 retarder and/or a λ/4 retarder. The polarizer may also be a film type or liquid crystal coating type polarizer. The film type may include an elongation-type synthetic resin, and the liquid crystal coating type may include liquid crystals that are arranged in a predetermined arrangement. Each of the phase retarder and the polarizer may further include a protection film. The retarder and polarizer itself or a protection film may be defined as the base layer of the optical layer 300.

The optical layer 300 according to an embodiment of the inventive concept may include color filters. The color filters may have predetermined arrangement. The color filters may be determined in arrangement in consideration of colors of light emitted from pixels provided in the display panel 100. The optical layer 300 may further include a black matrix adjacent to the color filters. The optical layer 300 including the color filters may be disposed directly on the display panel 100.

The window WM according to an embodiment of the inventive concept may include a base layer and a light blocking pattern. The base layer may include a glass substrate and/or a synthetic resin film. The light blocking pattern may partially overlap the base layer. The light blocking pattern may be disposed on a rear surface of the base layer, and the light blocking pattern may substantially define the bezel area DD-NDA (see FIG. 1) of the display device DD. An area on which the light blocking pattern is not disposed may define the image area DD-DA (see FIG. 1) of the display device DD.

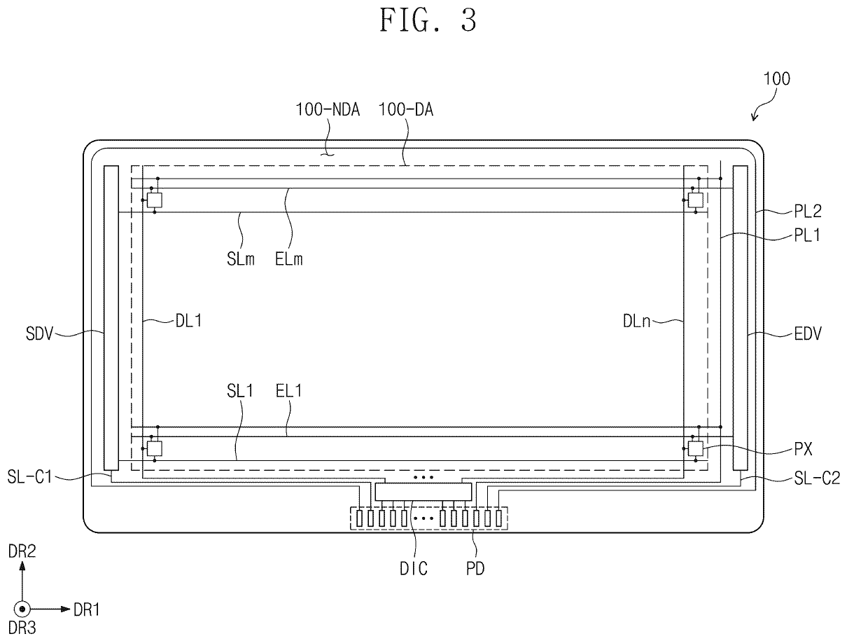

FIG. 3 is a plan view illustrating the display panel 100 according to an embodiment of the inventive concept.

Referring to FIG. 3, the display panel 100 may include a plurality of pixels PX, a scan driving circuit SDV, an emission driving circuit EDV, a plurality of signal lines, and a plurality of pads PD. The plurality of pixels PX may be disposed on a display area 100-DA. A driving chip DIC mounted in a non-display area 100-NDA may include a data driving circuit. The display area 100-DA may correspond to the image area DD-DA of FIG. 1, and the non-display area 100-NDA may correspond to the bezel area DD-NDA. In this specification, that “areas or portions correspond to each other” means overlapping each other, and is not necessarily limited to two different areas or portions having the same area. In an embodiment of the inventive concept, the data driving circuit may also be integrated into the display panel 100 like the scan driving circuit SDV and the emission driving circuit EDV.

The plurality of signal lines may include a plurality of scan lines SL1 to SLm, a plurality of data lines DL1 to DLn, a plurality of emission lines EL1 to ELm, first and second control lines SL-C1 and SL-C2, and first and second power lines PL1 and PL2, where m and n are natural numbers of 2 or more.

The scan lines SL1 to SLm may extend in the first direction DR1 and be electrically connected to pixels PX and the scan driving circuit SDV. The data lines DL1 to DLn may extend in the second direction DR2 and be electrically connected to the pixels PX and the driving chip DIC. The emission lines EL1 to ELm may extend in the first direction DR1 and be electrically connected to the pixels PX and the emission driving circuit EDV.

The first power line PL1 may receive a first power voltage, and the second power line PL2 may receive a second power voltage having a level less than that of the first power voltage. Although not shown, a second electrode (e.g., cathode) of the light emitting element may be connected to the second power line PL2.

The first control line SL-C1 may be connected to the scan driving circuit SDV and may extend toward a lower end of the display panel 100. The second control line SL-C2 may be connected to the emission driving circuit EDV and may extend toward the lower end of the display panel 100. The pads PD may be disposed on the non-display area 100-NDA adjacent to the lower end of the display panel 100 and may be closer to the lower end of the display panel 100 than the driving chip DIC. The pads PD may be connected to the driving chip DIC and some signal lines.

The scan driving circuit SDV may generate a plurality of scan signals, and the scan signals may be applied to the pixels PX through the scan lines SL1 to SLm. The driving chip DIC may generate a plurality of data voltages, and the data voltages may be applied to the pixels PX through the data lines DL1 to DLn. The emission driving circuit EDV may generate a plurality of emission signals, and the emission signals may be applied to the pixels PX through the emission lines EL1 to ELm. The pixels PX may receive the data voltages in response to the scan signals. The pixels PX may emit light having brightness corresponding the data voltages in response to the emission signals to display an image.

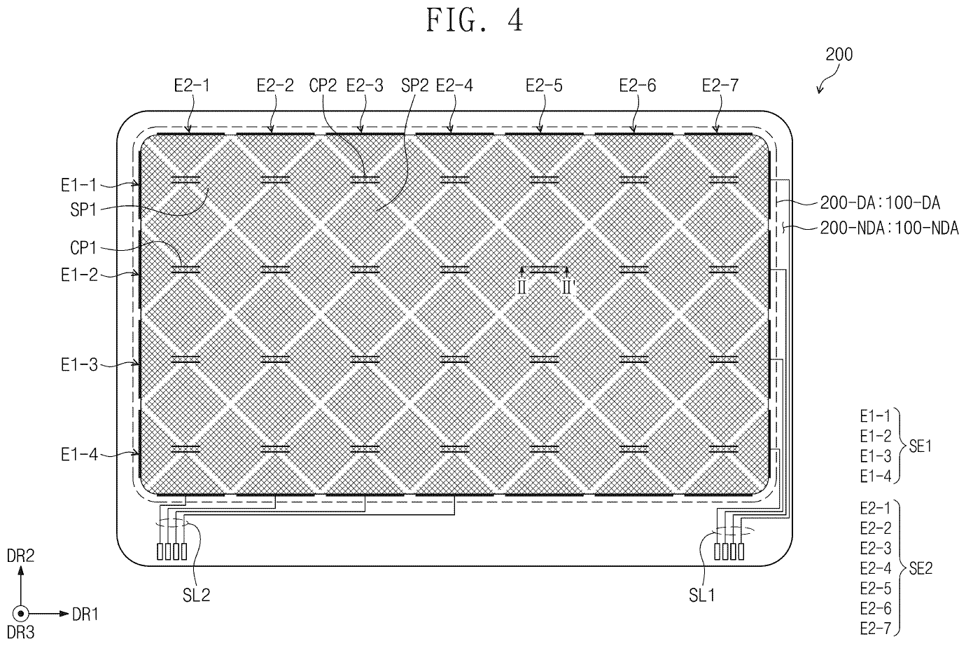

FIG. 4 is a plan view of the input sensing layer 200 according to an embodiment of the inventive concept.

As illustrated in FIG. 4, the input sensing layer 200 may include a sensing area 200-DA and a non-sensing area 200-NDA adjacent to the sensing area 200-DA. The sensing area 200-DA and the non-sensing area 200-NDA may correspond to the display area 100-DA and non-display area 100-NDA shown in FIG. 3, respectively.

The input sensing layer 200 may include the plurality of conductive patterns described above. The plurality of conductive patterns may include first electrodes SE1 (or first sensing electrodes), second electrodes SE2 (or second sensing electrodes), first signal lines SL1 (or first sensor signal lines), and second signal lines SL2 (or second sensor signal lines).

The first sensing electrodes SE1 and the second sensing electrodes SE2 that are insulated from each other and intersect each other may be disposed on the sensing area 200-DA. First signal lines SL1 connected to first sensing electrodes SE1 and second signal lines SL2 electrically connected to second sensing electrodes SE2 may be disposed on the non-sensing area 200-NDA. One of the first signal lines SL1 and the second signal lines SL2 may transmit a driving signal for sensing an external input from an external circuit to the corresponding electrodes, and the other may output a sensing signal. A change in capacitance between the first sensing electrodes SE1 and the second sensing electrodes SE2 may be measured based on the sensing signal. In this embodiment, a mutual cap type input sensor is illustrated as an example, but is not limited thereto. A self-cap type input sensor may also be applied. The self-cap type input sensor may include one type of sensing electrodes.

The first sensing electrodes SE1 may be provided in plurality of rows. The first sensing electrodes SE1 may include a first row sensing electrode E1-1, a second row sensing electrode E1-2, a third row sensing electrode E1-3, and a fourth row sensing electrode E1-4. Unlike as shown in FIG. 4, the first sensing electrodes SE1 may include two or three row sensing electrodes or may include five or more row sensing electrodes.

The second sensing electrodes SE2 may be provided in plurality of rows. The second sensing electrodes SE2 may include a first thermal sensing electrode E2-1, a second thermal sensing electrode E2-2, a third thermal sensing electrode E2-3, a fourth thermal sensing electrode E2-4, a fifth thermal sensing electrode E2-5, a sixth thermal sensing electrode E2-6, and a seventh thermal sensing electrode E2-7. Unlike as shown in FIG. 4, the second sensing electrodes SE2 may include six or fewer thermal sensing electrodes or may include eight or more thermal sensing electrodes.

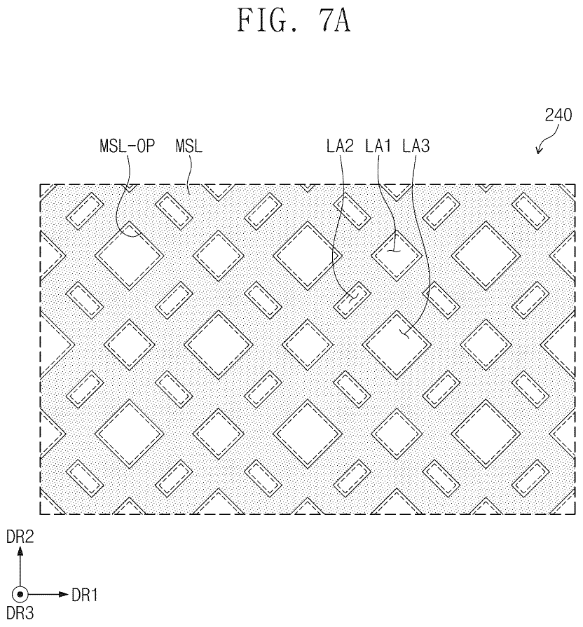

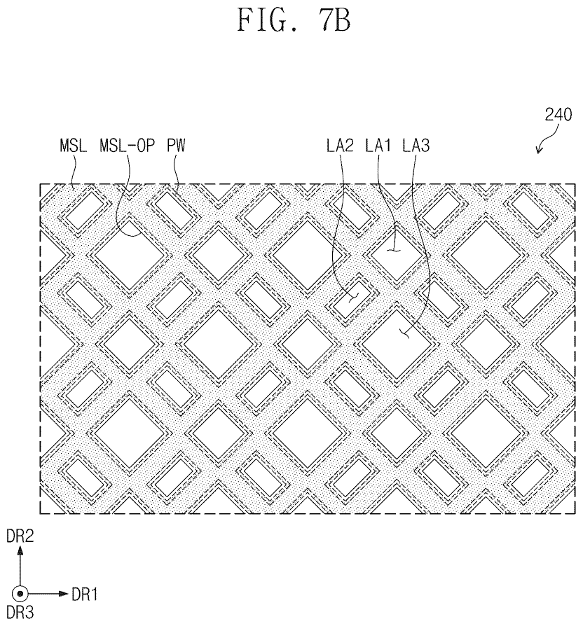

Each of the first sensing electrodes SE1 and the second sensing electrodes SE2 may have a mesh shape with a plurality of opening areas defined therein. The plurality of opening areas may, for example, overlap corresponding emission areas of the plurality of emission areas LA1, LA2 and LA3, see FIG. 7A for example. The second sensing electrodes SE2 are insulated and intersect the first sensing electrodes SE1. Either of the first sensing electrodes SE1 and the second sensing electrodes SE2 may have an integral shape. In this embodiment, second sensing electrodes SE2 having an integral shape are illustrated as an example.

The second sensing electrodes SE2 may include second sensing patterns SP2 and second bridge patterns CP2. The second sensing patterns SP2 may have a surface area greater than that of the second bridge patterns CP2 and may have a rhombus shape. Each of the second bridge patterns CP2 may be disposed between two adjacent second sensing patterns SP2 of the second sensing patterns SP2. A length of the second bridge patterns CP2 may be relatively short, and the second bridge patterns CP2 may be omitted. Here, the second sensing pattern SP2 may directly extend from the adjacent second sensing pattern SP2.

Each of the first sensing electrodes SE1 may include first sensing patterns SP1 and first bridge patterns CP1. Two adjacent first sensing patterns SP1 may be connected by two first bridge patterns CP1, but the number of bridge patterns is not limited.

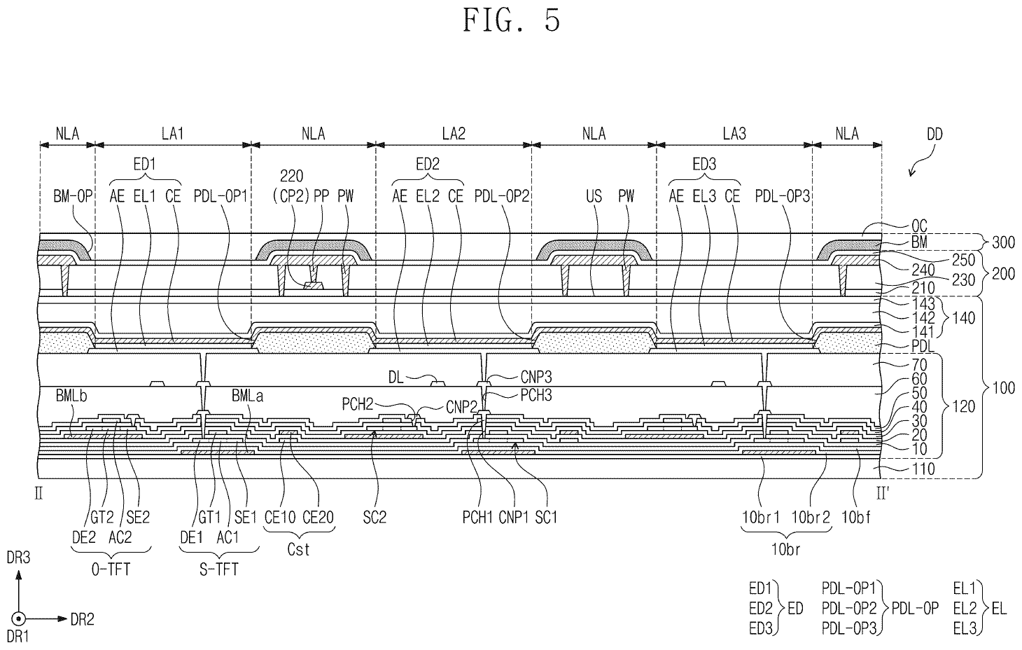

FIG. 5 is a cross-sectional view of the display device DD along the line II-II′ of FIG. 4 according to an embodiment of the inventive concept.

Referring to FIG. 5, a barrier layer 10br may be disposed on the base layer 110. The barrier layer 10br may prevent foreign substances from being introduced from the outside. The barrier layer 10br may include at least one inorganic layer. The barrier layer 10br may include a silicon oxide layer and a silicon nitride layer. Each of the silicon oxide layer and the silicon nitride layer may be provided in plurality, and the silicon oxide layers and silicon nitride layers may be alternately laminated.

The barrier layer 10br may include a lower barrier layer 10br1 and an upper barrier layer 10br2. A first shielding electrode BMLa may be disposed between the lower barrier layer 10br1 and the upper barrier layer 10br2. The first shielding electrode BMLa may be disposed to correspond to a silicon transistor S-TFT. The first shielding electrode BMLa may include a metal, such as molybdenum.

The first shield electrode BMLa may receive a bias voltage. The first shield electrode BMLa may also receive a first power voltage. The first shielding electrode BMLa may block an electric potential caused by polarization from affecting the silicon transistor S-TFT. The first shielding electrode BMLa may block external light from reaching the silicon transistor S-TFT. In an embodiment of the inventive concept, the first shielding electrode BMLa may be a floating electrode that is isolated from other electrodes or lines.

A buffer layer 10bf may be disposed on the barrier layer 10br. The buffer layer 10bf may prevent metal atoms or impurities from being diffused from the base layer 110 to a first semiconductor pattern SC1 disposed at the upper side. The buffer layer 10bf may include at least one inorganic layer. The buffer layer 10bf may include a silicon oxide layer and a silicon nitride layer.

The first semiconductor pattern SC1 may be disposed on the buffer layer 10bf. The first semiconductor pattern SC1 may include a silicon semiconductor. For example, the silicon semiconductor may include amorphous silicon, polycrystalline silicon, etc. For example, the first semiconductor pattern SC1 may include low-temperature polysilicon.

The first semiconductor pattern SC1 may have different electrical properties depending on whether the first semiconductor pattern SC1 is doped. The first semiconductor pattern SC1 may include a first region having high conductivity and a second region having low conductivity. The first region may be doped with an N-type dopant or a P-type dopant. The second region may be an undoped region or a region doped at a lower concentration than the first region. A source region SE1, a channel region AC1 (or active region), and a drain region DE1 of the silicon transistor S-TFT may be provided from the first semiconductor pattern SC1. The source region SE1 and the drain region DE1 may extend in opposite directions from the channel region AC1 in a cross-section.

A first insulating layer 10 may be disposed on the buffer layer 10bf. The first insulating layer 10 may cover the first semiconductor pattern SC1. The first insulating layer 10 may be an inorganic layer. The first insulating layer 10 may be a single-layered silicon oxide layer. The inorganic layer of the driving element layer 120 described later as well as the first insulating layer 10 may have a single-layer or multi-layer structure and may include at least one of the materials described above, but is not limited thereto.

A gate GT1 of the silicon transistor S-TFT may be disposed on the first insulating layer 10. The gate GT1 may be a portion of a metal pattern. The gate GT1 may overlap the channel region AC1. In the process of doping the first semiconductor pattern SC1, the gate GT1 may be a mask. A first electrode CE10 of a storage capacitor Cst may be disposed on the first insulating layer 10. Unlike that shown in FIG. 5, the first electrode CE10 may have an integral shape with the gate GT1.

A second insulating layer 20 may be disposed on the first insulating layer 10 to cover the gate GT1. In an embodiment of the inventive concept, an upper electrode overlapping the gate GT1 may be further disposed on the second insulating layer 20. A second electrode CE20 overlapping the first electrode CE10 may be disposed on the second insulating layer 20. The upper electrode may have an integral shape with the second electrode CE20 on the plane.

A second shielding electrode BMLb may be disposed on the second insulating layer 20. The second shielding electrode BMLb may be disposed to correspond to an oxide transistor O-TFT. In an embodiment of the inventive concept, the second shielding electrode BMLb may be omitted. According to an embodiment of the inventive concept, the first shielding electrode BMLa may extend to a lower portion of the oxide transistor O-TFT to replace the second shielding electrode BMLb.

A third insulating layer 30 may be disposed on the second insulating layer 20. A second semiconductor pattern SC2 may be disposed on the third insulating layer 30. The second semiconductor pattern SC2 may include a channel region A C2 of the oxide transistor O-TFT. The second semiconductor pattern SC2 may include a metal oxide semiconductor. The second semiconductor pattern SC2 may include transparent conductive oxide (TCO) such as indium tin oxide (ITO), indium zinc oxide (IZO), indium gallium zinc oxide (IGZO), zinc oxide (ZnOₓ), or indium oxide (In₂O₃).

The metal oxide semiconductor may include a plurality of regions SE2, A C2, and DE2 distinguished depending on whether the transparent conductive oxide is reduced or not. The region in which the transparent conductive oxide is reduced (hereinafter, referred to as a reduced region) has greater conductivity than a region in which the transparent conductive oxide is not reduced (hereinafter, referred to as a non-reduced region). The reduced region may essentially act as a source/drain or signal line of the transistor. The non-reduced region may essentially correspond to a semiconductor region (or channel) of the transistor. A fourth insulating layer 40 may be disposed on the third insulating layer 30. As illustrated in FIG. 5, the fourth insulating layer 40 may cover the second semiconductor pattern SC2. In an embodiment of the inventive concept, the fourth insulating layer 40 may be an insulating pattern that overlaps a gate GT2 of the oxide transistor O-TFT and exposes the source region SE2 and drain region DE2 of the oxide transistor O-TFT.

The gate GT2 of the oxide transistor O-TFT may be disposed on the fourth insulating layer 40. The gate GT2 of an oxide transistor O-TFT may be a portion of the metal pattern. The gate GT2 of the oxide transistor O-TFT may overlap the channel region A C2. A fifth insulating layer 50 may be disposed on the fourth insulating layer 40, and the fifth insulating layer 50 may cover the gate GT2. Each of the first insulating layer 10 to the fifth insulating layer 50 may be an inorganic layer.

A first connection pattern CNP1 and a second connection pattern CNP2 may be disposed on the fifth insulating layer 50. Since the first connection pattern CNP1 and the second connection pattern CNP2 are formed through the same process, the first connection pattern CNP1 and the second connection pattern CNP2 may have the same material and the same laminated structure. The first connection pattern CNP1 may be connected to the drain region DE1 of the silicon transistor S-TFT through a first pixel contact hole PCH1 passing through the first to fifth insulating layers 10, 20, 30, 40, and 50. The second connection pattern CNP2 may be connected to the source region SE2 of the oxide transistor O-TFT through a second pixel contact hole PCH2 passing through the fourth and fifth insulating layers 40 and 50. The connection relationship between the first connection pattern CNP1 and the second connection pattern CNP2 for the silicon transistor S-TFT and the oxide transistor O-TFT is not necessarily limited thereto.

A sixth insulating layer 60 may be disposed on the fifth insulating layer 50. A third connection pattern CNP3 may be disposed on the sixth insulating layer 60. The third connection pattern CNP3 may be connected to the first connection pattern CNP1 through a third pixel contact hole PCH3 passing through the sixth insulating layer 60. A data line DL may be disposed on the sixth insulating layer 60. A seventh insulating layer 70 may be disposed on the sixth insulating layer 60 to cover the third connection pattern CNP3 and the data line DL. The third connection pattern CNP3 and data line DL may be formed through the same process and thus may have the same material and the same laminated structure. Each of the sixth insulating layer 60 and the seventh insulating layer 70 may be an organic layer.

The light emitting elements ED may be provided in plurality. The plurality of light emitting elements ED may include a first light emitting element ED1, a second light emitting element ED2, and a third light emitting element ED3. The first light emitting element ED1 may have a first emission area LA1 that emits light having a first color. The second light emitting element ED2 may have a second emission area LA2 that emits light having a second color different from the first color. The third light emitting element ED3 may have a third emission area LA2 that emits light having a third color different from the first and second colors.

The first light emitting element ED1 may include a first electrode AE, a first emission layer EL1, and a second electrode CE. The second light emitting element ED2 may include a first electrode AE, a second emission layer EL2, and a second electrode CE. The third light emitting element ED3 may include a first electrode AE, a third emission layer EL3, and a second electrode CE. The first electrode AE and the second electrode CE of the first, second, and third light emitting elements ED1, ED2, ED3 may collectively be referred to as the anode AE and the cathode CE of the light emitting element ED. The anode AE of the light emitting element ED may be disposed on the seventh insulating layer 70. The anode AE may be a (semi) transparent electrode or a reflective electrode. The anode AE may include a sequentially stacked layered structure of ITO/Ag/ITO. The positions of the anode AE and cathode CE may be interchanged with each other.

A pixel defining layer PDL may be disposed on the seventh insulating layer 70. The pixel defining layer PDL may be an organic layer. The pixel defining layer PDL may have light-absorbing properties, for example, the pixel defining layer PDL may have a black color. The pixel defining layer PDL may include a black coloring agent. The block coloring agent may include a black dye and a black pigment. The black coloring agent may include carbon black, a metal such as chromium, or oxides thereof. The pixel defining layer PDL may correspond to a light blocking pattern having light blocking characteristics.

The pixel defining layer PDL may cover a portion of the anode AE. For example, the pixel defining layer PDL may have an opening PDL-OP that exposes a portion of the anode AE. Each of the emission areas LA1, LA2, and LA3 may be defined to correspond to the opening PDL-OP. The opening PDL-OP of the pixel defining layer PDL may be described as a “light emitting opening”. The light emitting openings PDL-OP may be provided in plurality. The plurality of light emitting openings PDL-OP may include a first light emitting opening PDL-OP1 overlapping, e.g., above, the first emission area LA1 (or defining the first emission area LA1), a second light emitting opening PDL-OP2 overlapping, e.g., above, the second emission area LA2 (or defining the second emission area LA2), and a third light emitting opening PDL-OP3 overlapping, e.g., above, the third emission area LA3 (or defining the third emission area LA3). The first light emitting opening PDL-OP1 may expose at least a portion of the first electrode AE of the first light emitting element ED1. The second light emitting opening PDL-OP2 may expose at least a portion of the first electrode AE of the second light emitting element ED2. The third light emitting opening PDL-OP3 may expose at least a portion of the first electrode AE of the third light emitting element ED3.

The first to third emission layers EL1, EL2, and EL3, collectively the emission layer EL, may be disposed on the first electrode AE and the pixel defining layer PDL. The first to third emission layers EL1, EL2, and EL3 may be disposed in the first to third light emitting openings PDL-OP1, PDL-OP2, and PDL-OP3, respectively. The first emission layer EL1 may overlap, e.g., be within, the first light emitting opening PDL-OP1 and may be disposed on the first electrode AE of the first light emitting element ED1. The second emission layer EL2 may overlap, e.g., be within, the second light emitting opening PDL-OP2 and may be disposed on the first electrode AE of the second light emitting element ED2. The third emission layer EL3 may overlap, e.g., be within, the third light emitting opening PDL-OP3 and may be disposed on the first electrode AE of the third light emitting element ED3.

The second electrode CE may be disposed on the first to third emission layers EL1, EL2, and EL3 and the pixel defining layer PDL. The second electrode CE may overlap, e.g., be within, the first to third light emitting openings PDL-OP1, PDL-OP2, and PDL-OP3. The second electrode CE of the first light emitting element ED1 may overlap the first light emitting opening PDL-OP1 and may be disposed on the first emission layer EL1. The second electrode CE of the second light emitting element ED2 may overlap the second light emitting opening PDL-OP2 and may be disposed on the second emission layer EL2. The second electrode CE of the third light emitting element ED3 may overlap the third light emitting opening PDL-OP3 and may be disposed on the third emission layer EL3. In an embodiment, the second electrodes CE of the first to third light emitting elements ED1, ED2, and ED3 may be provided as a common layer and provided as an integral electrode.

In FIG. 5, the first to third emission layers EL1, EL2, and EL3 may be illustrated as being disposed on the first electrodes AE of the first to third light emitting elements ED1, ED2, and ED3 and the pixel defining film PDL, but are not limited thereto. For example, the first to third emission layers EL1, EL2, and EL3 may be disposed only on the first electrodes AE of the first to third light emitting elements ED1, ED2, and ED3.

The first to third emission layers EL1, EL2, and EL3 may provide different colors. For example, the first emission layer EL1 may provide red light, the second emission layer EL2 may provide green light, and the third emission layer EL3 may provide blue light.

In an embodiment of the inventive concept, a hole control layer may be disposed between the anode AE and the emission layer EL. The hole control layer may include a hole transport layer and may further include a hole injection layer. An electronic control layer may be disposed between the emission layer EL and the cathode CE. The electronic control layer includes an electron transport layer and may further include an electron injection layer.

The encapsulation layer 140 may cover the light emitting element ED. The encapsulation layer 140 may include a sequentially laminated encapsulating inorganic layer 141, an encapsulating organic layer 142, and an encapsulating inorganic layer 143, but the layers constituting the encapsulation layer 140 are not necessarily limited thereto. Each of the encapsulation inorganic layers 141 and 143 may include a silicon nitride layer, a silicon oxynitride layer, a silicon oxide layer, a titanium oxide layer, or an aluminum oxide layer. Each of the encapsulation inorganic layers 141 and 143 may have a multilayer structure. The encapsulation organic layer 142 may include an acrylic-based organic layer, but is not limited thereto.

The input sensing layer 200 may include a plurality of conductive patterns. The input sensing layer 200 may include at least one conductive layer (or at least one sensor conductive layer) including conductive patterns and at least one insulating layer (or at least one sensor insulating layer). In this embodiment, the input sensing layer 200 may include a first sensor insulating layer 210, a first sensor conductive layer 220, a second sensor insulating layer 230, a second sensor conductive layer 240, a third sensor insulating layer 250, and partition walls PW. FIG. 5 briefly illustrates a plurality of conductive patterns included in each of the first sensor conductive layer 220 and the second sensor conductive layer 240.

The first sensor insulating layer 210 may be disposed directly on the display panel 100. The first sensor insulating layer 210 may be disposed directly on the encapsulation layer 140. The first sensor insulating layer 210 may be disposed between the encapsulation layer 140 and the first sensor conductive layer 220. The first sensor insulating layer 210 may be an inorganic layer including at least one of silicon nitride, silicon oxynitride, or silicon oxide. The first sensor insulating layer 210 may be omitted.

The first sensor conductive layer 220 may be disposed on the encapsulation layer 140 and/or the first sensor insulating layer 210. The second sensor conductive layer 240 may be disposed on the first sensor conductive layer 220. Each of the first sensor conductive layer 220 and the second sensor conductive layer 240 may have a single-layer structure or a multi-layer structure laminated along the third direction DR3. The first sensor conductive layer 220 and the second sensor conductive layer 240 may include conductive lines defining mesh-shaped electrodes. The conductive line of the first sensor conductive layer 220 and the conductive line of the second sensor conductive layer 240 may or may not be connected through a contact hole passing through the second sensor insulating layer 230 depending on their positions.

The first sensor conductive layer 220 and the second sensor conductive layer 240 of the single-layer structure may include a metal layer or a transparent conductive layer. The metal layer may include molybdenum, silver, titanium, copper, aluminum, or an alloy thereof. The transparent conductive layer may include a transparent conductive oxide such as indium-tin oxide (ITO), indium-zinc oxide (IZO), zinc oxide (ZnOₓ), or indium zinc tin oxide (IZTO). In addition, the transparent conductive layer may include a conductive polymer such as PEDOT, a metal nanowire, graphene, etc.

Each of the first sensor conductive layer 220 and the second sensor conductive layer 240 having the multilayer structure may include a plurality of metal layers. The metal layers may have a 3-layer structure of titanium/aluminum/titanium. Alternatively, the multi-layered conductive layer may include at least one metal layer and at least one transparent conductive layer.

Each of the first sensor conductive layer 220 and the second sensor conductive layer 240 may include at least some of the first sensing patterns SP1, the second sensing patterns SP2, the first bridge patterns CP1, and the second bridge patterns CP2, which are described above. FIG. 5 illustrates an embodiment in which the second bridge patterns CP2 constitutes the first sensor conductive layer 220, and the first sensing patterns SP1, the second sensing patterns SP2, and the first bridge patterns CP1 constitute the second sensor conductive layer 240. However, this is merely an example, and the conductive patterns constituting each of the first sensor conductive layer 220 and the second sensor conductive layer 240 may have various combinations and are not limited to any one embodiment.

The second sensor insulating layer 230 may be disposed between the first sensor conductive layer 220 and the second sensor conductive layer 240. The second sensor insulating layer 230 may be disposed between the encapsulation layer 140 and the second sensor conductive layer 240 and may be disposed on the first sensor insulating layer 210. The second sensor insulating layer 230 may cover a plurality of first conductive patterns included in the first sensor conductive layer 220. The second sensor insulating layer 230 may include at least one of silicon nitride, silicon oxide, silicon oxynitride, or aluminum oxide. Here, the second sensor insulating layer 230 may be provided as a plurality of inorganic layers. However, it is not limited to one embodiment, and the second sensor insulating layer 230 may include an organic insulating material. Here, the second sensor insulating layer 230 may be provided as a single layer. That is, the second sensor insulating layer 230 may include an inorganic layer or an organic layer.

The third sensor insulating layer 250 (or sensor cover layer) may cover a plurality of second conductive patterns included in the second sensor conductive layer 240. In an embodiment of the inventive concept, the third sensor insulating layer 250 (or sensor cover layer) may be omitted. The third sensor insulating layer 250 may be replaced with an adhesive layer or an insulating layer of an optical layer 300 disposed on the input sensing layer 200. The second sensor insulating layer 230 and the third sensor insulating layer 250 (or sensor cover layer) may include an inorganic layer or an organic layer.

The partition walls PW may be connected to the second sensor conductive layer 240 to pass through at least the second sensor insulating layer 230. In this embodiment, the partition walls PW may be in contact with a top surface of the encapsulation layer 140. However, this embodiment is not limited thereto.

The partition walls PW may include a conductive material. In this embodiment, each of the partition walls PW may be provided integrally with the second sensor conductive layer 240. For example, each of the partition walls PW may be provided by extending from some of the first sensing patterns SP1, the second sensing patterns SP2, and the first connecting patterns CP1. The partition walls PW may include the same material as the second sensor conductive layer 240. That is, the partition walls PW may be provided through the same process as the second sensor conductive layer 240. However, this is an example, and each of the partition walls PW may be provided separately from the second sensor conductive layer 240 and is not limited to any one embodiment.

Some of the partition walls PW may be connected to one of the second bridge patterns CP2 through the second sensor conductive layer 240 and through-parts PP. Some of the second bridge patterns CP2 may be connected to the second sensing patterns SP2 (see FIG. 4) by passing through the second sensor insulating layer 230 and may be spaced apart from the through-parts PP.

The partition walls PW may be provided along edges of the emitting areas LA1, LA2, and LA3. Since the partition walls PW are disposed adjacent to corresponding emission areas LA1, LA2, and LA3 of the emission areas LA1, LA2, and LA3, light leakage to non-emission area NLA may be blocked, and light collection efficiency and light extraction efficiency in the emission areas LA1, LA2, and LA3 may be improved. This will be described later in detail.

The optical layer 300 may be disposed on the input sensing layer 200. The optical layer 300 may include a light blocking layer BM and a planarizing layer OC. The optical layer 300 may reduce reflectivity of light incident from the outside of the display panel 100 (see FIG. 3) to improve external light visibility of the display panel 100 (see FIG. 3).

A material forming a light blocking layer BM is not particularly limited as long as it is a material that absorbs light. The light blocking layer BM may be a layer having a black color, and in an embodiment, the light blocking layer BM may include a black coloring agent. The black coloring agent may include a black dye and a black pigment. The black coloring agent may include carbon black, a metal such as chromium, or oxides thereof.

The light blocking layer BM may overlap the first sensor conductive layer 220 and the second sensor conductive layer 240 on the plane. The light blocking layer BM may prevent external light reflection by the first sensor conductive layer 220 and the second sensor conductive layer 240. A light blocking openings BM-OP may be defined in the light blocking layer BM. The light blocking openings BM-OP of the light blocking layer BM may overlap the anode AE and have a surface area greater than that of the light emitting openings PDL-OP of the pixel defining layer PDL.

The planarizing layer OC may cover the light blocking layer BM. The planarizing layer OC may include an organic material, and the planarizing layer OC may provide a flat top surface.

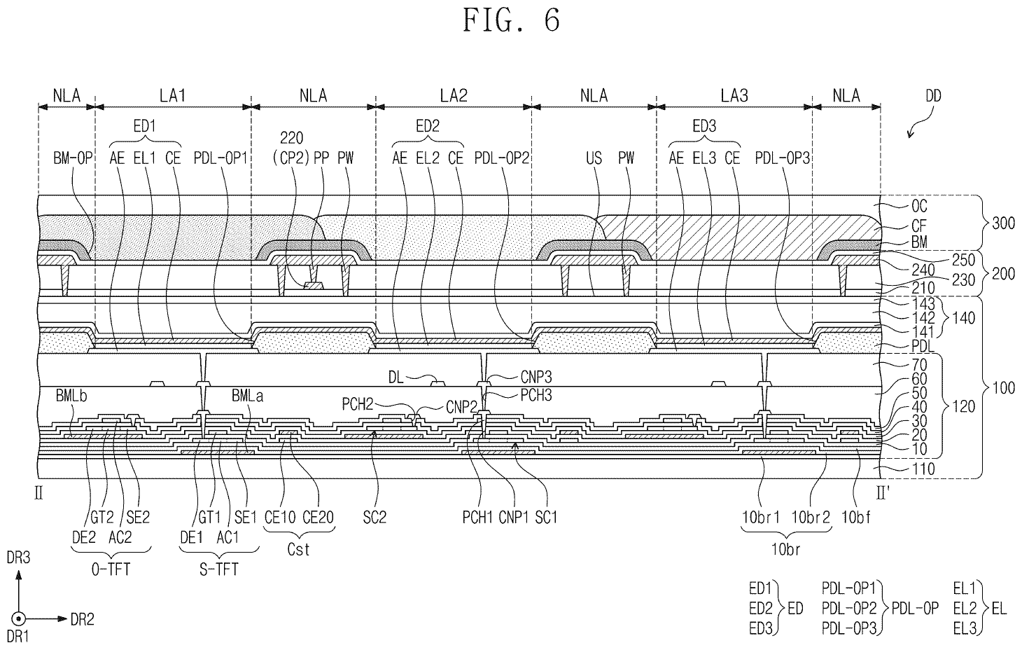

FIG. 6 is a cross-sectional view of the display device DD along the line II-II′ of FIG. 4 according to an embodiment of the inventive concept. Hereinafter, in description with reference to FIG. 6, the same/similar reference symbols are used for configurations identical/similar to those described in FIG. 5, and duplicated descriptions will be omitted.

Referring to FIG. 6, the optical layer 300 may further include a light blocking layer BM, a planarizing layer OC, and a color filter CF. The color filter CF may be disposed on the input sensing layer 200. The color filter CF may overlap, e.g., be above, at least each of the emission areas LA1, LA2, and LA3. A portion of the color filter CF may further overlap the non-emission area NLA. A portion of the color filter CF may be disposed on the light blocking layer BM. The color filter CF may transmit light generated by the light emitting element ED and block partial wavelengths of external light. Thus, the color filter CF may reduce external light reflection by the anode AE or the cathode CE.

The planarizing layer OC may cover the color filter CF. The planarizing layer OC may include organic matter and provide a flat top surface.

FIGS. 7A and 7B are enlarged plan views illustrating a portion of the display area of the display panel 100 (see FIG. 3) according to an embodiment of the inventive concept. FIGS. 7A and 7B illustrate enlarged views of a portion of the display area 100-DA (see FIG. 3) of the display panel 100 (see FIG. 3). FIGS. 7A and 7B illustrate a second sensor conductive layer 240 when viewed on the display surface DD-IS (see FIG. 1) of the display module DM (see FIG. 2).

Referring to FIGS. 7A and 7B, the second sensor conductive layer 240 may include a plurality of mesh lines MSL as described above. The mesh lines MSL may define a plurality of mesh openings MSL-OP.

The plurality of mesh openings MSL-OP may correspond one-to-one to the emission areas LA1, LA2, and LA3. FIGS. 7A and 7B illustrate the emission areas LA1, LA2, and LA3 divided into three groups according to light emitting colors.

The emission areas LA1, LA2, and LA3 may have different areas depending on the color emitted from the emission layer EL of the organic light emitting element OLED. A surface area of each of the emission areas LA1, LA2, and LA3 may be determined depending on the type of organic light emitting element OLED.

In the above, the mesh openings MSL-OP may be illustrated as one-to-one corresponding to the emission areas LA1, LA2, and LA3, but are not limited thereto. One mesh opening MSL-OP may correspond to two or more emitting areas LA1, LA2, and LA3.

In FIGS. 7A and 7B, the surface areas of the emission areas LA1, LA2, and LA3 may be illustrated as being various, but are not limited thereto. Sizes of the emission areas LA1, LA2, and LA3 may be the same, and sizes of the mesh openings MSL-OP may also be the same.

Referring to FIG. 7B, the partition walls PW may overlap the second sensor conductive layer 240. Top surfaces of the partition walls PW may be entirely covered by the second sensor conductive layer 240. The partition walls PW may surround the emission areas LA1, LA2, and LA3 respectively on the plane. In FIG. 7B, top surfaces of the partition walls PW may be partially or entirely uncovered by the second sensor conductive layer 240. The sizes of the emission areas LA1, LA2, and LA3 (see FIG. 7A) may be the same, and the sizes of the partition walls PW may also be the same.

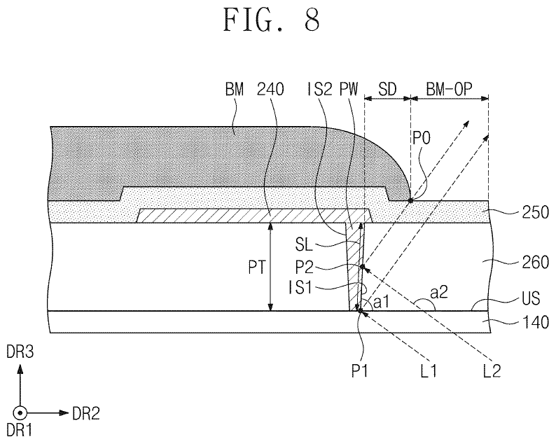

FIG. 8 is a cross-sectional view of the display device DD according to an embodiment of the inventive concept. FIG. 8 illustrates an enlarged view of a portion of the display module DM (see FIG. 2). Hereinafter, in description with reference to FIG. 8, the same/similar reference symbols are used for components that are identical/similar to those described in FIGS. 5 to 7, and duplicated descriptions will be omitted.

In this embodiment, a sensor insulating layer 260 may be illustrated as a single layer. That is, the sensor insulating layer 260 disposed between the encapsulation layer 140 and the third sensor insulating layer 250 may be provided as a single layer. The partition wall PW may extend from a bottom surface of the second sensor conductive layer 240, pass through the sensor insulating layer 260, and be in contact with a top surface US of the encapsulation layer 140.

The partition wall PW may include a first surface IS1 facing the emission area, and a second surface IS2 opposite to the first surface IS1. The first surface IS1 may be inclined at a predetermined angle a1 (hereinafter, referred to as an inclination angle) with respect to the top surface US of the encapsulation layer 140. The inclination angle a1 may be less than about 90 degrees, i.e., be an acute angle.

The first surface IS1 of the partition wall PW may be spaced apart from the light blocking opening BM-OP. In a cross-section, a minimum spaced distance SD (hereinafter, referred to as a spaced distance between the light blocking opening BM-OP and the partition wall PW) between a side surface of the light blocking layer BM defining the light blocking opening BM-OP and the first surface IS1 may correspond to a distance measured at the uppermost point of the first surface IS1, i.e., a point connected to the second sensor conductive layer 240. A length SL (hereinafter, referred to as a first length) of the first surface of the partition wall PW may be greater than the spaced distance SD between the light blocking opening BM-OP and the partition wall PW.

In FIG. 8, a path of light generated from the light emitting element ED (see FIG. 5) is illustrated as an arrow for easy explanation. In the light generated from the light emitting element ED (see FIG. 5), light emitted toward the partition wall PW may be reflected from the first surface IS1 of the partition wall PW. A first light path L1 may be a path of light incident on the lowest end of the partition wall PW, that is, in this embodiment, a point P1 (hereinafter, referred to as a first point) that is in contact with the top surface US of the encapsulation layer 140 on the first surfaces IS1. A second optical path L2 may be a path of light reflected from the partition wall PW that passes through a point P0 at which the light blocking opening BM-OP and the third sensor insulating layer 250 are in contact with each other.

In this embodiment, a predetermined range of the first surface IS1 of the partition wall PW may be defined as an effective emission portion. The effective emission portion may be referred to as a portion at which light incident on the first surface IS1 is reflected by the partition wall PW to pass through the light blocking opening BM-OP to the outside without being trapped in the light blocking layer BM.

When the first surface IS1 is a total reflection surface, light incident above the first point P1 through which the first light path L1 passes may be emitted into the light emitting opening PDL-OP. The second light path L2 incident onto a second point P2 may be totally reflected by the partition PW and then may be emitted to the outside through an end of the light blocking opening BM-OP. Light incident to an upper side of the second point P2 of the first surface IS1 may be absorbed by the light blocking layer BM without being emitted to the outside. That is, the point P2 at which one light is incident onto the first surface IS1 may be the uppermost point P2 of the effective emission portion. Thus, the effective emission portion may be defined as a range from the point P1 through which the first light path L1 passes to the point P2 through which the second light path L2 passes in the length SL of the first surface IS1 in the cross-section.

Since the effective emission portion is defined on a partial area of the first surface IS1, the cross-sectional length of the effective emission portion (hereinafter, referred to as a second length) may be less than the first length SL.

When the inclination angle a1 between the first surface IS1 and the top surface US of the encapsulation layer 140 is θ, and an angle a2 (or second angle) between the light incident toward the partition wall PW along the second light path L2 and the top surface US of the encapsulation layer 140 is about 1.5 θ, a distance between the first point P1 and the second point P2 may be equal to a spaced distance SD between the light blocking opening BM-OP and the partition wall PW. That is, the distance between the first point P1 and the second point P2 may be equal to the first length SL minus the spaced distance SD between the light blocking opening BM-OP and the partition wall PW. The first length SL may be greater than the spaced distance SD between the light blocking opening BM-OP and the partition wall PW. Thus, a light emitting effective portion having a predetermined area may be secured on the first surface IS1 of the partition wall PW.

When the angle defined between the first surface IS1 and the top surface US of the encapsulation layer 140 is referred to as the inclination angle a1 (or first angle), a vertical length PT of the partition wall PW may be equal to the product of a sine (sin) value for the inclination angle a1 (or first angle) and the first length SL. According to an embodiment of the inventive concept, as the first length SL and the vertical length PT of the partition wall PW increase, an amount of light reflected by the partition wall PW and emitted to the outside through the light blocking opening BM-OP may increase to improve light efficiency. In addition, according to an embodiment of the inventive concept, the smaller the inclination angle a1 (or the first angle), the greater the emission effect through the partition wall PW. That is, as the spaced distance SD between the light blocking opening BM-OP and the partition wall PW and the vertical length PT of the partition wall PW increase, and the angle a1 (or the first angle) defined between the first surface IS1 and the top surface of the encapsulation layer 140 decreases, the length of the effective emission portion of the first surface IS1 of the partition wall PW may increase.

The vertical length PT of the partition wall PW may be less than the spaced distance SD between the light blocking opening BM-OP and the partition wall PW. When the sensor insulating layer 260 is provided as an inorganic layer, since there is a process limitation of increasing in thickness of the sensor insulating layer 260, the vertical length PT of the partition wall PW may be provided to be about 0.5 μm or less. The spaced distance SD between the light blocking opening BM-OP and the partition wall PW may be less than about 0.5 μm.

In this embodiment, when the sensor insulating layer 260 is provided as the organic layer, the thickness of the sensor insulating layer 260 may be easily controlled compared to when the sensor insulating layer 260 is provided as the inorganic layer. Specifically, when the sensor insulating layer 260 is provided as the organic layer, the first length SL and the vertical length PT of the partition wall PW may be greater than that when provided as the inorganic layer. Thus, the emission effect due to the total reflection may be greater when the sensor insulating layer 260 is provided as the organic layer rather than the inorganic layer.

The partition wall PW may be in contact with the top surface US of the encapsulation layer 140. The top surface US of the encapsulation layer 140 may be the uppermost surface of the encapsulation layer 140, and in this embodiment, the top surface US may be a top surface of the encapsulating inorganic layer 143 (see FIG. 5). However, this is an example, and if the uppermost layer of the encapsulation layer 140 is an organic film, the top surface US of the encapsulation layer 140 may also be an organic layer and is not limited to any one embodiment.

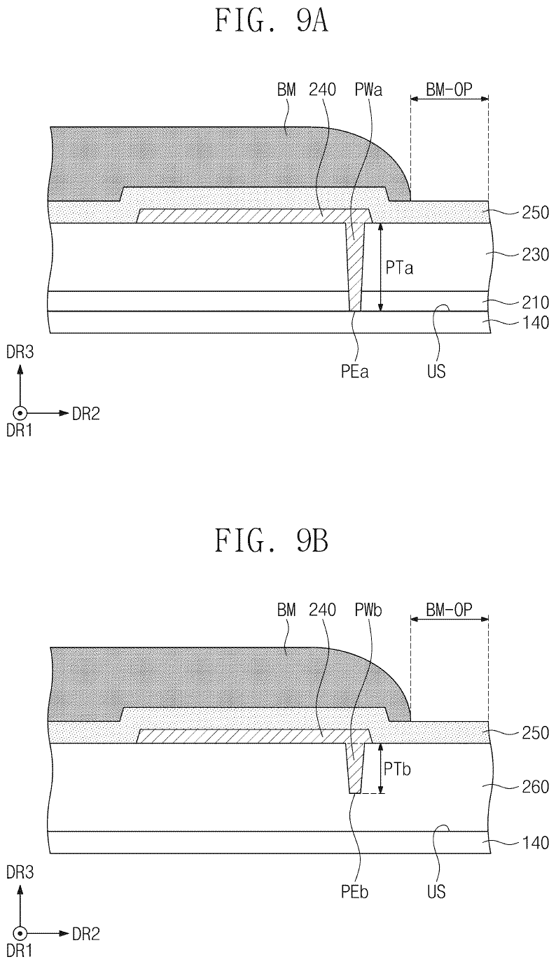

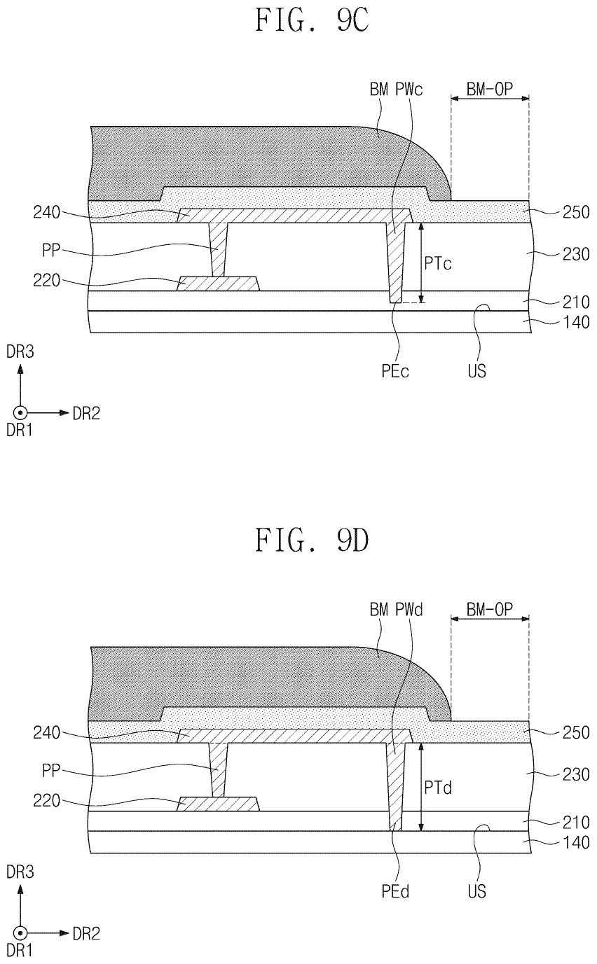

FIGS. 9A to 9D are cross-sectional views of the display device DD according to an embodiment of the inventive concept. Hereinafter, in descriptions with reference to FIGS. 9A to 9D, the same/similar reference numerals may be used for components that are the same/similar to those described in FIGS. 5 to 8, and duplicated descriptions thereof may be omitted.

Referring to FIG. 9A, the sensor insulating layer may be provided as a plurality of layers. The sensor insulating layer may include a first sensor insulating layer 210 and a second sensor insulating layer 230.

The first sensor insulating layer 210 may be disposed on the encapsulation layer 140. The first sensor insulating layer 210 may be disposed between the encapsulation layer 140 and the second sensor conductive layer 240. The second sensor insulating layer 230 may be disposed on the first sensor insulating layer 210. The second sensor insulating layer 230 may be disposed between the first sensor insulating layer 210 and the third sensor insulating layer 250. In this embodiment, an end PE a of a partition wall PW a may be in contact with the top surface US of the encapsulation layer 140. The partition wall PW a may pass through the first sensor insulating layer 210 and the second sensor insulating layer 230. That is, the partition wall PW a may pass through the first sensor insulating layer 210 and the second sensor insulating layer 230 and be in contact with the top surface US of the encapsulation layer 140.

Here, a vertical length PT a of the partition wall PW a may be equal to the sum of thicknesses of the first sensor insulating layer 210 and the second sensor insulating layer 230. The vertical length PT a of the partition wall PW a may be greater than the spaced distance SD (see FIG. 8) between the light blocking opening BM-OP and the partition wall PWa.

Referring to FIG. 9B, in this embodiment, the sensor insulating layer 260 may be provided as a single layer. The sensor insulating layer 260 may be disposed between the encapsulation layer 140 and the third sensor insulating layer 250.

In this embodiment, an end PEb of a partition wall PWb may be inserted into the sensor insulating layer 260. The end PEb of the partition wall PWb may be in non-contact with the top surface US of the encapsulation layer 140. The partition wall PWb may pass through only a portion of the sensor insulating layer 260.

Here, a vertical length PTb of the partition wall PWb may be less than the thickness of the sensor insulating layer 260. The vertical length PTb of the partition wall PWb may be greater than the spaced distance SD (see FIG. 8) from the first surface IS1 to the light blocking opening BM-OP.

Referring to FIG. 9C, the sensor insulating layer may be provided as a plurality of layers. The sensor insulating layer may include a first sensor insulating layer 210 and a second sensor insulating layer 230.

The first sensor insulating layer 210 may be disposed on the encapsulation layer 140. The first sensor insulating layer 210 may be disposed between the encapsulation layer 140 and the second sensor conductive layer 240. The second sensor insulating layer 230 may be disposed on the first sensor insulating layer 210. The second sensor insulating layer 230 may be disposed between the first sensor insulating layer 210 and the third sensor insulating layer 250.

In this embodiment, an end PEc of a partition wall PWc may be inserted into the first sensor insulating layer 210. The partition wall PWc may be in non-contact with the top surface US of the encapsulation layer 140. The partition wall PWc may pass through only a portion of the first sensor insulating layer 210 and the second sensor insulating layer 230.

Here, a vertical length PTc of the partition wall PWc may be smaller than the sum of the thicknesses of the first sensor insulating layer 210 and the second sensor insulating layer 230. The vertical length PTc of the partition wall PWc may be greater than the spaced distance SD (see FIG. 8) between the light blocking opening BM-OP and the partition wall PW c.

A portion of the partition walls PWc may be connected to one of the second bridge patterns CP2 (see FIG. 4) through the second sensor conductive layer 240. The thickness of each of the through-parts PP connected to the second sensing patterns SP2 (see FIG. 4) through the second sensor insulating layer 230 from the plurality of second bridge patterns CP2 (see FIG. 4) may be smaller than the vertical length PTc of the partition wall PWc.

Referring to FIG. 9D, the sensor insulating layer may be provided as a plurality of layers. The sensor insulating layer may include a first sensor insulating layer 210 and a second sensor insulating layer 230.

The first sensor insulating layer 210 may be disposed on the encapsulation layer 140. The first sensor insulating layer 210 may be disposed between the encapsulation layer 140 and the second sensor conductive layer 240. The second sensor insulating layer 230 may be disposed on the first sensor insulating layer 210. The second sensor insulating layer 230 may be disposed between the first sensor insulating layer 210 and the third sensor insulating layer 250.

In this embodiment, an end PEd of a partition wall PWd may be in contact with the top surface US of the encapsulation layer 140. The partition wall PWd may pass through the first sensor insulating layer 210. That is, the partition wall PWd may pass through the first sensor insulating layer 210 and the second sensor insulating layer 230 and be in contact with the top surface US of the encapsulation layer 140.

Here, a vertical length PTd of the partition wall PWd may be equal to the sum of the thicknesses of the first sensor insulating layer 210 and the second sensor insulating layer 230. The vertical length PTd of the partition wall PWd may be greater than the spaced distance SD (see FIG. 8) between the light blocking opening BM-OP and the partition wall PWd.

A portion of the partition walls PWd may be connected to one of the second bridge patterns CP2 (see FIG. 4) through the second sensor conductive layer 240. The thickness of each of the through-parts PP connected to the second sensing patterns SP2 (see FIG. 4) through the second sensor insulating layer 230 from the plurality of second bridge patterns CP2 (see FIG. 4) may be smaller than the vertical length PT d of the partition wall PW d.

According to the present disclosure, the optical characteristics of the display device may be improved by extracting the light trapped at the lower portion of the light blocking patterns by utilizing the total reflection by the upper sensor conductive layer of the input sensing layer included in the display device.

It will be apparent to those skilled in the art that various modifications and variations can be made in the inventive concept. Thus, it is intended that the present disclosure covers the modifications and variations of the inventive concept provided they come within the scope of the appended claims and their equivalents. Hence, the real protective scope of the inventive concept shall be determined by the technical scope of the accompanying claims.

What is claimed is:

1. A display device comprising:
a display panel comprising a plurality of emission areas and non-emission areas, the display panel comprising a plurality of light emitting elements respectively disposed on the emission areas and an encapsulation layer configured to cover the light emitting elements;
a light blocking layer disposed on the display panel and having light blocking openings above the emission areas, respectively; and
an input sensing layer disposed between the display panel and the light blocking layer,
wherein the input sensing layer comprises:
a first sensor conductive layer disposed on the encapsulation layer;
a second sensor conductive layer on the first sensor conductive layer;
a sensor insulating layer disposed between the encapsulation layer and the second sensor conductive layer; and
partition walls connected to the second sensor conductive layer and passing through at least a portion of the sensor insulating layer,
wherein each of the partition walls comprises a first surface facing one of the emission areas and a second surface that is opposite to the first surface.

2. The display device of claim 1, wherein the partition walls are configured to surround the emission areas, respectively.

3. The display device of claim 1, wherein the partition walls are in contact with a top surface of the encapsulation layer.

4. The display device of claim 1, wherein the sensor insulating layer comprises a plurality of layers, and
wherein the plurality of layers comprise:
a first sensor insulating layer disposed between the encapsulation layer and the first sensor conductive layer; and
a second sensor insulating layer disposed between the encapsulation layer and the second sensor conductive layer and disposed on the first sensor insulating layer,
wherein the partition walls pass through at least the second sensor insulating layer.

5. The display device of claim 4, wherein the partition walls further pass through at least a portion of the first sensor insulating layer.

6. The display device of claim 4, wherein the partition walls are in contact with the encapsulation layer.

7. The display device of claim 4, wherein the second sensor insulating layer comprises at least one of silicon nitride, silicon oxide, silicon oxynitride, and aluminum oxide.

8. The display device of claim 4, wherein the second sensor insulating layer comprises an organic insulating material.

9. The display device of claim 1, wherein a spaced distance between a partition wall of the partition walls facing one emission area of the emission areas and a light blocking opening of the light blocking openings above the emission area on a plane is 0.5 μm or less.

10. The display device of claim 9, wherein a length of the first surface is greater than the spaced distance.

11. The display device of claim 1, wherein the second sensor conductive layer comprises:
a plurality of first sensing patterns arranged along a first direction;
each of a plurality of first bridge patterns disposed between the first sensing patterns to connect adjacent first sensing patterns of the first sensing patterns to each other; and
a plurality of second sensing patterns arranged along a second direction intersecting the first direction,
wherein the first sensor conductive layer comprises each of a plurality of second bridge patterns disposed between the second sensing patterns on a plane and passing through the second sensor insulating layer so as to be connected to adjacent second sensing patterns of the second sensing patterns,
wherein a portion of the partition walls is connected to any one of the second bridge patterns through the second sensor conductive layer.

12. The display device of claim 11, wherein each of through-parts connected to the second sensing patterns by passing through the second sensor insulating layer from the plurality of second bridge patterns has a thickness less than a thickness of each of the partition walls.

13. The display device of claim 1, wherein an angle defined between the first surface and a top surface of the encapsulation layer is an acute angle.

14. The display device of claim 1, wherein the second sensor conductive layer and the partition walls comprise a same material.

15. The display device of claim 1, further comprising an optical layer disposed on the input sensing layer and comprising a plurality of color filters respectively overlapping the plurality of emission areas.

16. An electronic device comprising:
a display panel comprising a plurality of emission areas and non-emission areas, the display panel comprising a plurality of light emitting elements respectively disposed on the emission areas and an encapsulation layer configured to cover the light emitting elements;
a light blocking layer disposed on the display panel and having light blocking openings above the emission areas, respectively; and
an input sensing layer disposed on the display panel,
wherein the input sensing layer comprises:
a sensor conductive layer disposed on the encapsulation layer;
an insulating layer disposed between the encapsulation layer and the sensor conductive layer; and
partition walls connected to the sensor conductive layer and passing through at least a portion of the insulating layer,
wherein a thickness of each of the partition walls is greater than a spaced distance between a partition wall of the partition walls facing one emission area of the emission areas and a light blocking opening of the light blocking openings above the emission area on a plane.

17. The electronic device of claim 16, wherein the sensor conductive layer and the partition walls comprise a same material.

18. The electronic device of claim 16, wherein the partition walls are in contact with a top surface of the encapsulation layer.

19. The electronic device of claim 16, wherein the spaced distance is 0.5 μm or less.

20. The electronic device of claim 16, further comprising an optical layer disposed on the input sensing layer and comprising a plurality of color filters respectively overlapping the plurality of emission areas.
